(19) United States
(12) Patent Application Publication
(10) Pub. No.: US 2015/0194478 A1
(43) Pub. Date: Jul. 9, 2015

(54) Capacitors and Methods of Forming Capacitors

(71) Applicant: Micron Technology, Inc., Boise, ID (US)

(72) Inventors: Vassil N. Antonov, Boise, ID (US); Vishwanath Bhat, Boise, ID (US)

(73) Assignee: Micron Technology, Inc., Boise, ID (US)

(21) Appl. No.: 14/147,424

(22) Filed: Jan. 3, 2014

(51) Int. Cl. H01L 49/02

(52) U.S. Cl. CPC H01L 28/84

(57) ABSTRACT

A method of forming a capacitor includes forming an elevationally elongated and elevationally inner capacitor electrode that comprises different composition laterally-outermost and laterally-innermost conductive portions that have different respective intrinsic residual mechanical stress. The innermost conductive portion is formed to have greater mechanical stress in the compressive direction than the outermost conductive portion. A capacitor dielectric is formed over the inner capacitor electrode and an elevationally outer capacitor electrode is formed over the capacitor dielectric. A capacitor construction independent of the method formed is disclosed.

### TECHNICAL FIELD

Embodiments disclosed herein pertain to capacitors and to methods of forming capacitors.

### BACKGROUND

Capacitors are one type of component used in the fabrication of integrated circuits, for example in logic, DRAM, and other memory circuitry. A capacitor is comprised of two conductive electrodes separated by a non-conducting dielectric region. As integrated circuitry density has increased, there is a continuing challenge to maintain sufficiently high storage capacitance despite decreasing capacitor area. The increase in density has typically resulted in greater reduction in the horizontal dimension of capacitors as compared to the vertical dimension. In many instances, the vertical dimension of capacitors has increased.

One manner of fabricating capacitors is to initially form a support material within which a capacitor storage electrode is formed. For example, an array of capacitor electrode openings for individual capacitors is fabricated in an insulative support material, with an example material being silicon dioxide doped with one or both of phosphorus and boron. Openings within which some or all of the capacitors are formed are etched into the support material. It can be difficult to etch such openings through the support material, particularly where the openings are deep and the support material is composed of multiple different materials.

Further and regardless, it is often desirable to etch away most if not all of the support material after individual capacitor electrodes have been formed within the openings. This enables outer sidewall surfaces of the electrodes to provide increased area and thereby increased capacitance for the capacitors being formed. However, capacitor electrodes formed in deep openings are often correspondingly much taller than they are wide. This can lead to toppling of the capacitor electrodes during etching to expose the outer sidewalls surfaces, during transport of the substrate, during deposition of the capacitor dielectric material, and/or outer capacitor electrode material. U.S. Pat. No. 6,667,502 teaches the provision of a brace or lattice-like retaining structure intended to alleviate such toppling. Other aspects associated with the formation of a plurality of capacitors, some of which include bracing structures, have also been disclosed, such as in:

U.S. Pat. No. 7,067,385;

U.S. Pat. No. 7,125,781;

U.S. Pat. No. 7,199,005;

U.S. Pat. No. 7,202,127;

U.S. Pat. No. 7,387,939;

U.S. Pat. No. 7,439,152;

U.S. Pat. No. 7,517,753;

U.S. Pat. No. 7,544,563;

U.S. Pat. No. 7,557,013;

U.S. Pat. No. 7,557,015;

U.S. Patent Publication No. 2008/0090416;

U.S. Patent Publication No. 2008/0206950;

U.S. Pat. No. 7,320,911;

U.S. Pat. No. 7,682,924; and

U.S. Patent Publication No. 2010/0009512.

The addition of one or more lattice structures to hold the elevationally inner capacitor electrode upright during fabrication can improve their stability, though adding complexity for the etching processes used in forming an array of capacitors.

### BRIEF DESCRIPTION OF THE DRAWINGS

FIG. 1 is a diagrammatic sectional view of a capacitor in accordance with an embodiment of the invention.

FIG. 2 is a sectional view taken through line 2-2 in FIG. 1.

FIG. 3 is a diagrammatic sectional view of a substrate in process in accordance with a method of forming a capacitor in accordance with an embodiment of the invention.

FIG. 4 is a sectional view taken through line 4-4 in FIG. 3.

FIG. 5 is a view of the FIG. 3 substrate at a processing step subsequent to that shown by FIG. 3.

FIG. 6 is a view of the FIG. 5 substrate at a processing step subsequent to that shown by FIG. 5.

FIG. 7 is a diagrammatic sectional view of another capacitor in accordance with an embodiment of the invention.

FIG. 8 is a diagrammatic sectional view of another capacitor in accordance with an embodiment of the invention.

FIG. 9 is a sectional view taken through line 9-9 in FIG. 8.

FIG. 10 is a diagrammatic sectional view of a substrate in process in a method of forming a capacitor in accordance with an embodiment of the invention.

FIG. 11 is a view of the FIG. 10 substrate at a processing step subsequent to that shown by FIG. 10.

FIG. 12 is a diagrammatic sectional view of another capacitor in accordance with an embodiment of the invention.

### DETAILED DESCRIPTION OF EXAMPLE EMBODIMENTS

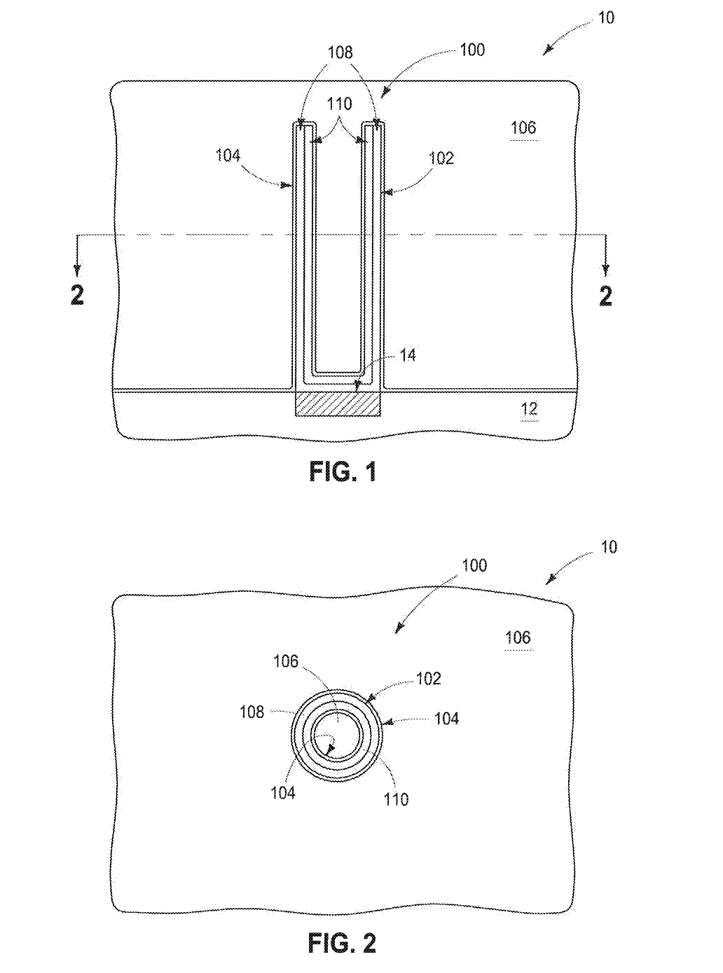

Embodiments of the invention encompass a capacitor independent of method of fabrication. FIGS. 1 and 2 show one example capacitor 100 as part of a construction 10. Capacitor 100 has been formed over a substrate 12, which may comprise a semiconductor substrate. In the context of this document, the term “semiconductor substrate” or “semiconductive substrate” is defined to mean any construction comprising semiconductive material, including, but not limited to, bulk semiconductive materials such as a semiconductive wafer (either alone or in assemblies comprising other materials thereon), and semiconductive material layers (either alone or in assemblies comprising other materials). The term “substrate” refers to any supporting structure, including, but not limited to, the semiconductive substrates described above. Capacitor 100 comprises an elevationally elongated and elevationally inner capacitor electrode 102, a capacitor dielectric 104 that is over inner capacitor electrode 102, and an elevationally outer capacitor electrode 106 that is over capacitor dielectric 104. In this document, “elevational” and “elevationally” are with reference to the vertical direction relative to a base substrate upon which the circuitry has been or is being fabricated. Vertical is a direction generally orthogonal to horizontal, with horizontal referring to a general direction along a primary surface relative to which a substrate is processed during fabrication. Further, “vertical” and “horizontal” as used herein are generally perpendicular directions relative one another independent of orientation of the substrate in three-dimensional space.

Example inner capacitor electrode 102 is shown to be of an upwardly-open cylinder shape closed at its lower end (thereby also being of a container shape), although any elevationally elongated shape may be used. Regardless, elevationally inner capacitor electrode 102 comprises laterally-outermost and laterally-innermost conductive (i.e., electrically conductive) portions 108, 110, respectively, that are of different composition and have different respective intrinsic residual mechanical stress. Laterally-innermost conductive portion 110 is formed to have greater mechanical stress in the compressive direction than laterally-outermost conductive portion 108, for example as will be described below with respect to some more specific embodiments.

Any of the materials and/or structures described herein may be homogenous or non-homogenous, and regardless may be continuous or discontinuous over any material that such overlie. As used herein, “different composition” only requires those portions of two stated materials that may be directly against one another to be chemically and/or physically different, for example if such materials are not homogenous. If the two stated materials are not directly against one another, “different composition” only requires that those portions of the two stated materials that are closest to one another be chemically and/or physically different if such materials are not homogenous. In this document, a material or structure is “directly against” another when there is at least some physical touching contact of the stated materials or structures relative one another. In contrast, “over”, “on”, and “against” not preceded by “directly”, encompass “directly against” as well as construction where intervening material(s) or structure(s) result(s) in no physical touching contact of the stated materials or structures relative one another. Further, unless otherwise stated, each material may be formed using any suitable or yet-to-be-developed technique, with atomic layer deposition, chemical vapor deposition, physical vapor deposition, epitaxial growth, diffusion doping, and ion implanting being examples.

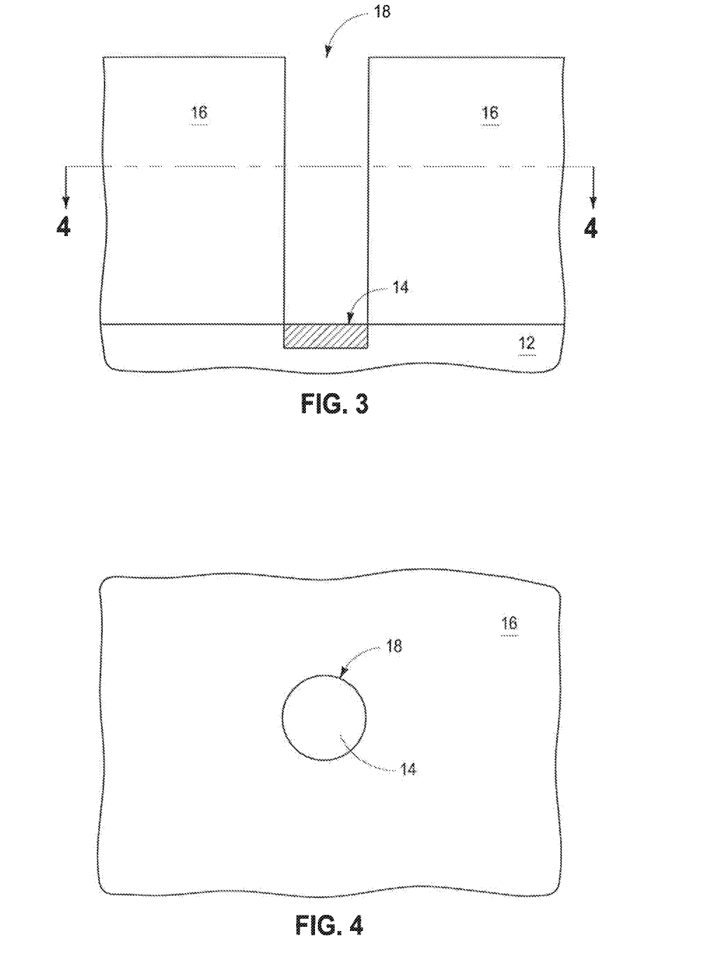

Example methods of forming capacitors in accordance with embodiments of the invention are next described initially with reference to FIGS. 3-6 in formation of a capacitor like that of FIGS. 1 and 2. The discussion proceeds with respect to fabrication of a single capacitor, although thousands or millions of such may be formed essentially simultaneously. Referring to FIGS. 3 and 4 a construction including substrate 12 comprises a conductive node location 14 which may correspond to, for example, a conductively-doped diffusion region within a semiconductive material of substrate 12 and/or to conductive pedestals associated with substrate 12. Conductive node location 14 may ultimately be electrically connected with transistor or other constructions (not shown), may correspond to a source/drain region of a transistor construction, or may be ohmically connected to source/drain regions of transistor constructions. As alternate examples, the node location may correspond to, connect to, or be part of a conductive interconnect line. Node location 14 may be electrically conductive at the processing stage of FIGS. 3 and 4 or may be made electrically conductive subsequently. A support material 16 has been formed elevationally over substrate 12. An opening 18 has been formed through support material 16 to node location 14. Example opening 18 is shown as being circular in horizontal cross-section, although any alternate shape may be used.

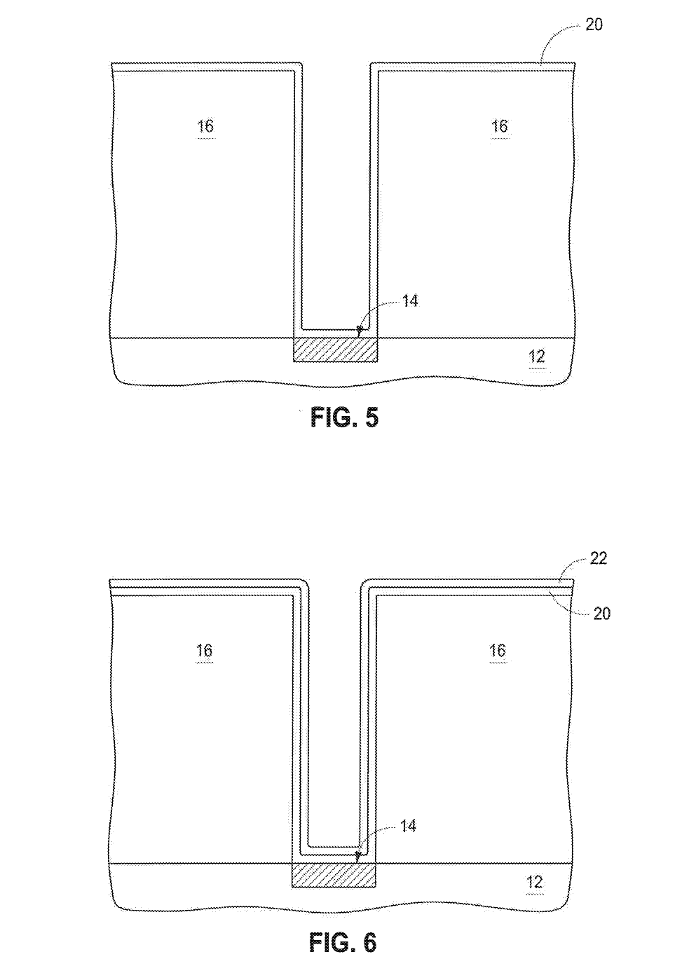

One embodiment of forming a cylinder shape of an elevationally inner capacitor electrode comprises at least two time-separated deposition steps (i.e., not a single time-continuous deposition) of conductive material to within an opening in support material to less-than-fill such opening. For example, FIG. 5 shows an initial deposition step in the forming of a conductive material 20 that will comprise at least part of laterally-outermost conductive portion 108 in FIGS. 1 and 2. FIG. 6 shows a last of the deposition steps in forming a different composition conductive material 22 that will comprise at least part of laterally-innermost conductive portion 110 of FIGS. 1 and 2. Lateral thicknesses of materials 20 and 22 may be the same or different relative one another, and which may be chosen depending upon the desired residual stress and the quantity of intrinsic residual mechanical stress of the different materials. Two different composition conductive materials 20, 22 may be considered as being shown in FIG. 6 although deposition of additional conductive material(s) may be used. Materials 20 and 22 may be directly against one another. Example conductive materials 20, 22, are elemental metals, alloys of elemental metals, conductive metal compounds, and suitably conductively-doped semiconductive materials. Specific examples include refractory metal nitrides, refractory metal silicides, ruthenium, platinum, iridium, nickel, and conductively-doped polysilicon.

To form a construction like that shown in FIGS. 1 and 2, materials 20 and 22 in FIG. 6 can be etched or polished back at least to the elevationally outermost surface of support material 16. Then, support material 16 can be removed by etching selectively relative to materials 20, 22 and 12, followed by deposition of materials of capacitor dielectric 104 and elevationally outer capacitor electrode 106. Material 20 thereby comprises or forms laterally-outermost conductive portion 108 and conductive material 22 comprises or forms laterally-innermost conductive portion 110.

Alternate techniques may be used in forming a cylinder shape, and regardless of whether support material is used. As an additional example, a method of forming a cylinder shape electrode includes depositing a conductive initial material within an opening in support material to less-than-fill the opening. For example, a conductive material may be deposited within a support material opening to have a desired final lateral thickness of the inner capacitor electrode. Regardless, less-than-all of the lateral thickness of that initial material is treated within the opening to increase intrinsic residual mechanical stress in the compressive direction and to form the laterally-innermost conductive portion. In one embodiment, the initial material is of substantially uniform composition at least prior to the treating. For example, a material could be deposited within a support material opening to have the final thickness of combined materials 20 and 22. The exposed portion thereof could then be treated such that only a thickness of the layer depicted by material 22 results in increased stress in the compressive direction, thereby ultimately resulting in the lateral conductive portions 108 and 110 in FIGS. 1 and 2.

Treating techniques that will increase mechanical stress in the compressive direction include methods that insert more atoms into the as-deposited material, with greater increase in mechanical stress in the compressive direction occurring by inserting atoms that are larger in size than the atoms in the as-deposited material. The treatment may include exposure to one or more of gas, liquid, and plasma. For example with respect to TiN, such may be treated with O₂ plasma, O₃ gas, and/or H₂O₂ (plasma, gas, or liquid) to introduce oxygen atoms whereby mechanical stress increases in the compressive direction. A specific example includes using a treating temperature of about 200° C. to 350° C. (of about 100° C. to 350° C. for plasma), pressure of about 0.1 Torr to 10 Torr, flow rate of the oxygen-containing treating material of about 0.1 1/min to 5 1/min, and a treating time of about 1 minute to 30 minutes sufficient to treat less than all of the entire thickness of the initially-deposited material.

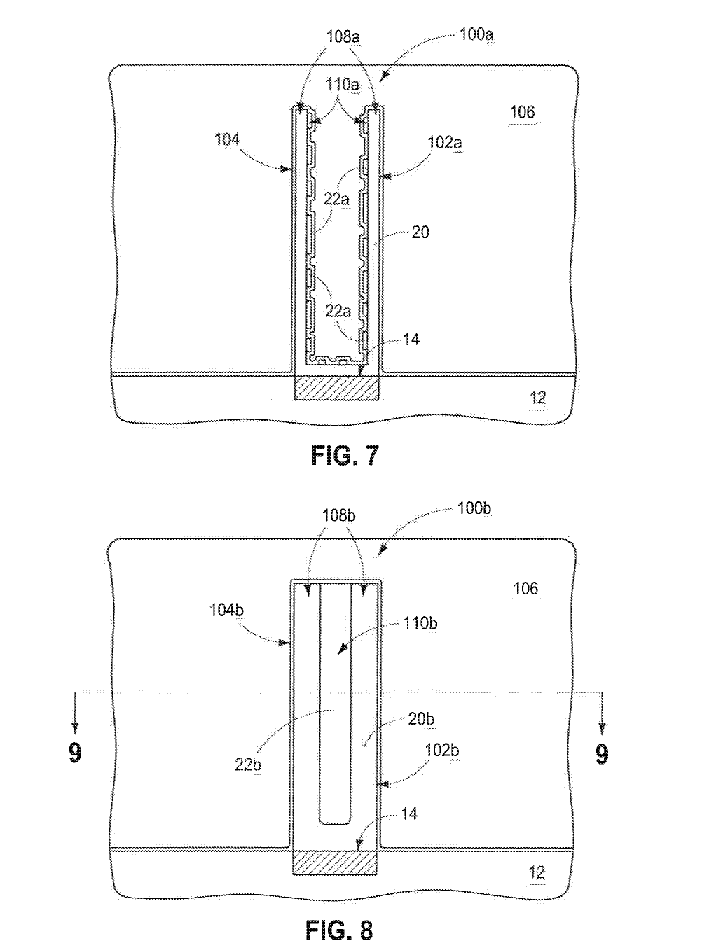

The treating may be conducted to form the laterally-innermost conductive portion to be of any desired lateral thickness. However in one embodiment, the treating forms a laterally-innermost conductive portion to have a lateral thickness that is no greater than 3 Angstroms. Regardless, the treating may form the laterally-innermost conductive portion to be longitudinally continuous or to be longitudinally discontinuous. FIGS. 1, 2, and 6 for such treating show the laterally-innermost conductive portion as being longitudinally continuous. An alternate example embodiment capacitor construction 100a is shown in FIG. 7. Like numerals from the above-described embodiments have been used where appropriate, with some construction differences being indicated with the suffix “a”. Laterally inner capacitor electrode 102a is shown as comprising laterally-outermost conductive portion 108a (e.g., slightly thicker than portion 108) and a laterally-innermost conductive portion 110a whereby material 22a is formed to be longitudinally discontinuous and accordingly laterally-innermost conductive portion 110a is longitudinally discontinuous.

An additional method of forming a cylinder shape capacitor electrode comprises time-continuously depositing conductive material (i.e., no stopping the deposition after starting until completed) within an opening in support material to less-than-fill the opening and until a desired lateral thickness of sidewalls of the cylinder shape within the opening is achieved. In a latter portion of the depositing, a deposition parameter is changed (i.e., at least one parameter) to increase intrinsic residual mechanical stress in the compressive direction in the deposited conductive material as compared to an initial portion of the depositing. For example, where the deposited material is crystalline, temperature may be lowered late in the deposition process to decrease crystalline grain size which tends to increase mechanical stress in the compressive direction. For example in chemical vapor deposition of TiN using TiCl₄ and NH₃ as precursors, pressure of about 0.1 Torr to 10 Torr, and a temperature range of about 300° C. to 500° C., a lower temperature in that range could be used later in the deposition process as compared to earlier in the deposition process to vary composition in the deposited TiN and increase mechanical stress in the compressive direction. As an additional alternate example, impurities could be introduced into the deposited material later in the deposition. Example impurities for TiN include introducing one or more of C, Al, O, W, and St. Impurities might be introduced later in the process inherently by reducing flow rate of one or both of the reactants later in the deposition process as compared to earlier in the deposition process. Additionally or alternately, two different precursors containing one constituent of the primary desired ultimate material may be used. For example, TiCl₄ and tetrakis(dimethylamido)titanium (TDMAT) may be used as titanium precursors, with TDMAT introducing carbon into the film. An initial portion of the deposition could be void of using TDMAT whereas a latter portion includes TDMAT. As an alternate example, TiCl₄ and TDMAT may be used as deposition precursors continuously throughout the deposition, with the relative flow rate of TDMAT being increased later in the deposition process (e.g., either by reducing TiCl₄ flow or increasing TDMAT flow). As an alternate example for introducing carbon, a precursor material can be used that does not contain either Ti or N (e.g., a hydrocarbon) during at least a later part of the deposition.

An additional method of forming a cylinder shape includes depositing conductive material within an opening in support material to less-than-fill the opening, and to less than a desired finished thickness for the elevationally inner capacitor electrode. That conductive material is then treated laterally-throughout (i.e., through all of its lateral thickness) to increase its intrinsic residual mechanical stress in the tensile direction. Then, conductor (i.e., electrically conductive) material is deposited over the treated conductive material within the opening to less-than-fill remaining volume of the opening, with the conductor material having greater mechanical stress in the compressive direction than the treated conductive material. The conductive material prior to its treating and the conductor material may be of the same composition and the same intrinsic residual mechanical stress. Alternately as an example, the conductive material prior to its treating and the conductor material may be of different composition and different intrinsic residual mechanical stress. Example techniques for treating a conductive material to increase intrinsic residual mechanical stress in the tensile direction include increasing grain size for crystalline materials and/or reducing impurities. For example for a refractory metal nitride, a treatment which would increase stress in the tensile direction might inject more nitrogen into the as-deposited material whereby the nitrogen substitutes for and drives out impurities from the as-deposited material. For example, a refractory metal nitride can be subjected to a nitrogen plasma or to ammonia (gas or plasma) to inject nitrogen atoms into the as-deposited material. Example parameters for such a treatment include a temperature of about 400° C. to 700° C.; pressure of about 0.1 Torr to 10 Torr, gas flow rate of a nitrogen-containing treating material of about 0.1 1/min to 10 1/min; and for a time period of about 5 minutes to 1 hour.

As an alternate example for increasing mechanical stress in the tensile direction, a thermal anneal of the as-deposited material may be conducted to increase crystal size. The same above parameters may be used in such a process wherein the atmosphere is largely inert to reaction or inert to insertion of atoms into the as-deposited material. As an alternate possible example, a refractory metal nitride may be annealed in H₂O vapor or in a manner which tends to remove impurity as opposed to injecting oxygen atoms therein. An example technique includes a temperature of about 200° C. to 400° C.; pressure of about 0.1 Torr to 10 Torr; H₂O flow rate of about 0.1 1/min to 10 1/min, and for a time period of 1 minute to 1 hour.

Techniques analogous to those described above for affecting intrinsic residual mechanical stress of TiN may be used for other refractory metal nitrides and for other conductive materials that are not refractory metal nitrides.

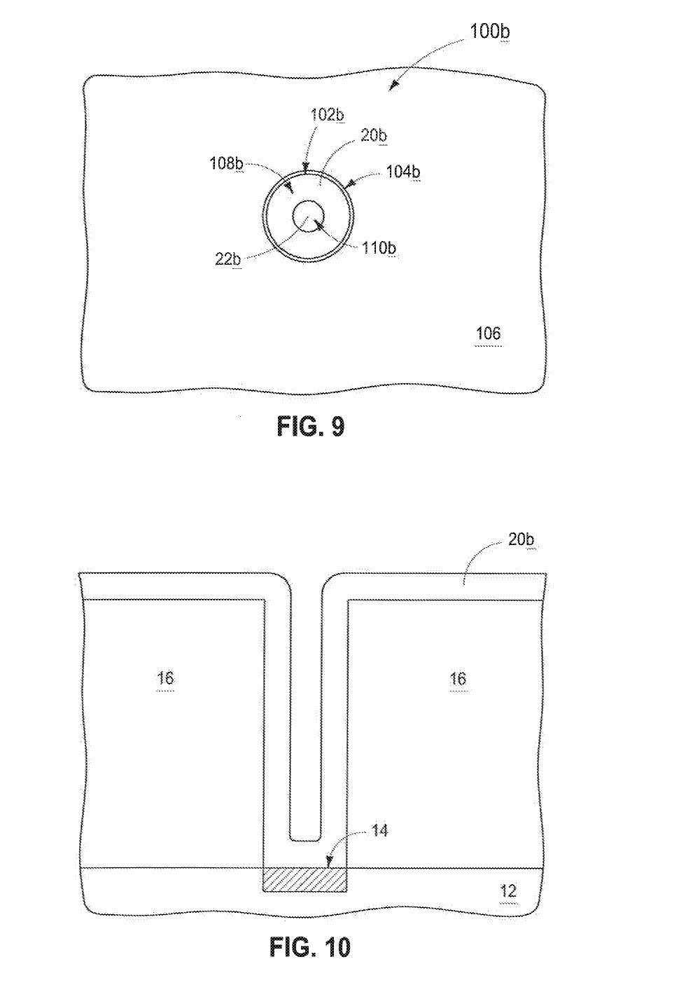

As an alternate example, the elevationally inner capacitor electrode may be formed to be an upwardly-closed pillar, and regardless of whether formed using support material. Example such embodiments are next described with reference to FIGS. 8-12. FIGS. 8 and 9 show a capacitor 100b comprising an elevationally inner capacitor electrode 102b in an example shape of an upwardly-closed pillar. Like numerals from the above-described embodiments have been used where appropriate, with some construction differences being indicated with the suffix “b” or with different numerals. Capacitor electrode 102b comprises different composition laterally-outermost and laterally-innermost conductive portions 108b, 110b, respectively. Laterally-innermost conductive portion 110b is formed to have greater mechanical stress in the compressive direction than laterally-outermost conductive portion 108b. Materials and methods analogous to those described above may be used in forming conductive portions 108b, 110b.

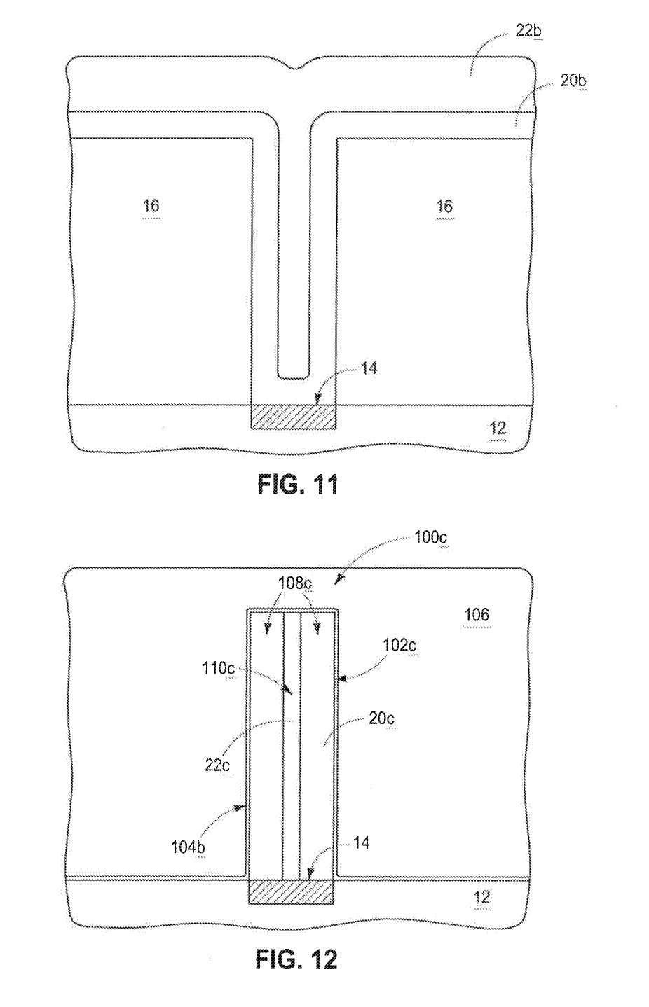

For example in one embodiment, a method of forming the pillar comprises at least two time-separated deposition steps of conductive materials to within an opening in support material. An initial of the deposition steps less-than-fills the opening and forms at least part of the laterally-outermost conductive portion. For example, FIG. 10 depicts deposition of material 20b within the opening in support material 16. Material 20b will at least in part form laterally-outermost conductive portion 108b in the finished capacitor construction. A last of the deposition steps fills remaining volume of the opening and forms at least part of laterally-innermost conductive portion 110b. For example, FIG. 11 shows deposition of conductive material 22b which fills remaining volume of the support material opening. Subsequent processing may be conducted to produce the structure of FIGS. 8 and 9. For example, materials 22b and 20b can be etched or polished back at least to support material 16, support material 16 etched thereafter selectively relative to materials 22b, 20b, and 12, followed by formation of capacitor dielectric 104b and elevationally outer capacitor electrode 106.

In another example embodiment, forming the pillar comprises time-continuously depositing conductive material into an opening in support material to fill the opening with the conductive material. A latter portion of the depositing comprises a deposition parameter change that increases intrinsic residual mechanical stress in the compressive direction in the deposited conductive material as compared to an initial portion of the depositing. Example techniques for doing so are as described above for increasing mechanical stress in the compressive direction.

As an additional example embodiment, a method of forming a pillar comprises depositing conductive material within an opening in support material to less-than-fill the opening. The conductive material is then treated laterally-throughout to increase its intrinsic residual mechanical stress in the tensile direction. Conductor material is then deposited over the treated conductive material within the opening to fill remaining volume of the opening with the conductor material. The conductor material has greater mechanical stress in the compressive direction than the treated conductive material. In one embodiment, the conductive material prior to its treating and the conductor material are of the same composition and the same intrinsic residual mechanical stress. In one embodiment, the conductive material prior to its treating and the conductor material are of different composition and different intrinsic residual mechanical stress. Techniques as described above for treating to increase intrinsic residual mechanical stress in the tensile direction are examples and may be used.

A method of forming a capacitor in accordance having an alternate construction is shown and described with reference to FIG. 12. Like numerals from the above-described embodiments have been used where appropriate, with some construction differences being indicated with the suffix “c” or with different numerals. Capacitor 100c of FIG. 12 is similar to that of FIG. 8 except wherein treated conductive material 22c does not extend continuously laterally across node location 14, and material 22c extends to node location 14. The embodiments of FIGS. 1 and 2 with respect to a cylinder shape may also be constructed such that material 20 does not extend continuously laterally across node location 14 (not shown).

As previously stated, the innermost conductive portion is formed to have greater mechanical stress in the compressive direction than the outermost conductive portion. However, the intrinsic residual mechanical stress of the laterally-innermost conductive portion of the elevationally inner capacitor electrode may be compressive or tensile. Additionally, the intrinsic residual mechanical stress of the laterally-outermost conductive portion may be tensile or may be compressive. Regardless, in one embodiment difference in intrinsic residual mechanical stress between the laterally-innermost conductive portion and the laterally-outermost conductive portion is at least 50 MPa. In one embodiment, difference in intrinsic residual mechanical stress between the laterally-innermost conductive portion and the laterally-outermost conductive portion is at most 2 GPa. Regardless, the laterally-innermost and laterally-outermost conductive portions may, respectively, be formed to be of laterally uniform or of laterally variable intrinsic residual mechanical stress.

Embodiments of the invention include a capacitor independent of the method of fabrication, and which may have one or more of the various attributes described above of capacitors produced in accordance with method embodiments of the invention.

### CONCLUSION

In some embodiments, a method of forming a capacitor comprises forming an elevationally elongated and elevationally inner capacitor electrode that comprises different composition laterally-outermost and laterally-innermost conductive portions that have different respective intrinsic residual mechanical stress. The innermost conductive portion is formed to have greater mechanical stress in the compressive direction than the outermost conductive portion. A capacitor dielectric is formed over the inner capacitor electrode and an elevationally outer capacitor electrode is formed over the capacitor dielectric.

In some embodiments, a capacitor comprises an elevationally elongated and elevationally inner capacitor electrode that comprises different composition laterally-outermost and laterally-innermost conductive portions that have different respective intrinsic mechanical stress. The innermost conductive portion has greater mechanical stress in the compressive direction than the outermost conductive portion. A capacitor dielectric is over the inner capacitor electrode and an elevationally outer capacitor electrode over the capacitor dielectric.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method of forming a capacitor, comprising:
forming an elevationally elongated and elevationally inner capacitor electrode that comprises different composition laterally-outermost and laterally-innermost conductive portions that have different respective intrinsic residual mechanical stress, the innermost conductive portion being formed to have greater mechanical stress in the compressive direction than the outermost conductive portion; and
forming a capacitor dielectric over the inner capacitor electrode and forming an elevationally outer capacitor electrode over the capacitor dielectric.

2. The method of claim 1 comprising forming the inner capacitor electrode to be of an upwardly-open cylinder shape.

3. The method of claim 2 wherein forming the cylinder shape comprises at least two time-separated deposition steps of conductive materials to within an opening in support material to less-than-fill the opening, an initial of the deposition steps forming at least part of the laterally-outermost conductive portion, a last of the deposition steps forming at least part of the laterally-innermost conductive portion.

4. The method of claim 2 wherein forming the cylinder shape comprises:
depositing a conductive initial material within an opening in support material to less-than-fill the opening;
treating less-than-all of lateral thickness of the initial material within the opening to increase intrinsic residual mechanical stress in the compressive direction in and to form the laterally-innermost conductive portion.

5. The method of claim 4 wherein the initial material is of substantially uniform composition at least prior to the treating.

6. The method of claim 4 wherein the treating forms the laterally-innermost conductive portion to be of lateral thickness that is no greater than 3 Angstroms.

7. The method of claim 4 wherein the treating forms the laterally-innermost conductive portion to be longitudinally continuous.

8. The method of claim 4 wherein the treating forms the laterally-innermost conductive portion to be longitudinally discontinuous.

9. The method of claim 2 wherein forming the cylinder shape comprises time-continuously depositing conductive material within an opening in support material to less-than-fill the opening and until a desired lateral thickness of sidewalls of the cylinder shape within the opening is achieved, a latter portion of the depositing comprising a deposition parameter change that increases intrinsic residual mechanical stress in the compressive direction in the deposited conductive material as compared to an initial portion of the depositing.

10. The method of claim 2 wherein forming the cylinder shape comprises:
depositing conductive material within an opening in support material to less-than-fill the opening;
treating the conductive material laterally-throughout to increase its intrinsic residual mechanical stress in the tensile direction; and
depositing conductor material over the treated conductive material within the opening to less-than-fill remaining volume of the opening, the conductor material having greater mechanical stress in the compressive direction than the treated conductive material.

11. The method of claim 10 wherein the conductive material prior to its treating and the conductor material are of the same composition and the same intrinsic residual mechanical stress.

12. The method of claim 10 wherein the conductive material prior to its treating and the conductor material are of different composition and different intrinsic residual mechanical stress.

13. The method of claim 1 comprising forming the inner capacitor electrode to be an upwardly-closed pillar.

14. The method of claim 13 wherein forming the pillar comprises at least two time-separated deposition steps of conductive materials to within an opening in support material, an initial of the deposition steps less-than-filling the opening and forming at least part of the laterally-outermost conductive portion, a last of the deposition steps filling remaining volume of the opening and forming at least part of the laterally-innermost conductive portion.

15. The method of claim 13 wherein forming the pillar comprises time-continuously depositing conductive material into an opening in support material to fill the opening with the conductive material, a latter portion of the depositing comprising a deposition parameter change that increases intrinsic residual mechanical stress in the compressive direction in the deposited conductive material as compared to an initial portion of the depositing.

16. The method of claim 13 wherein forming the pillar comprises:
depositing conductive material within an opening in support material to less-than-fill the opening;
treating the conductive material laterally-throughout to increase its intrinsic residual mechanical stress in the tensile direction; and
depositing conductor material over the treated conductive material within the opening to fill remaining volume of the opening with the conductor material, the conductor material having greater mechanical stress in the compressive direction than the treated conductive material.

17. The method of claim 16 wherein the conductive material prior to its treating and the conductor material are of the same composition and the same intrinsic residual mechanical stress.

18. The method of claim 16 wherein the conductive material prior to its treating and the conductor material are of different composition and different intrinsic residual mechanical stress.

19. The method of claim 1 wherein the intrinsic residual mechanical stress of the laterally-innermost conductive portion is compressive.

20. The method of claim 1 wherein the intrinsic residual mechanical stress of the laterally-innermost conductive portion is tensile.

21. The method of claim 1 wherein the intrinsic residual mechanical stress of the laterally-outermost conductive portion is tensile.

22. The method of claim 1 wherein the intrinsic residual mechanical stress of the laterally-outermost conductive portion is compressive.

23. The method of claim 1 wherein difference in intrinsic residual mechanical stress between the laterally-innermost conductive portion and the laterally-outermost conductive portion is at least 50 MPa.

24. The method of claim 1 wherein difference in intrinsic residual mechanical stress between the laterally-innermost conductive portion and the laterally-outermost conductive portion is at most 2 GPa.

25. The method of claim 1 comprising forming the laterally-innermost conductive portion to be laterally of uniform intrinsic residual mechanical stress.

26. The method of claim 1 comprising forming the laterally-innermost conductive portion to be laterally of variable intrinsic residual mechanical stress.

27. The method of claim 1 comprising forming the laterally-outermost conductive portion to be laterally of uniform intrinsic residual mechanical stress.

28. The method of claim 1 comprising forming the laterally-outermost conductive portion to be laterally of variable intrinsic residual mechanical stress.

29. A capacitor comprising:
an elevationally elongated and elevationally inner capacitor electrode that comprises different composition laterally-outermost and laterally-innermost conductive portions that have different respective intrinsic mechanical stress, the innermost conductive portion having greater mechanical stress in the compressive direction than the outermost conductive portion; and
a capacitor dielectric over the inner capacitor electrode and an elevationally outer capacitor electrode over the capacitor dielectric.
